(19) United States
(12) Patent Application Publication
(10) Pub. No.: US 2025/0301788 A1
(43) Pub. Date: Sep. 25, 2025

(54) ELECTRONIC PRINTING DEVICE AND METHOD FOR MANUFACTURING METAL PRINTED OBJECT USING THE SAME

(71) Applicant: InnoLux Corporation, Miao-Li County (TW)

(72) Inventors: Yu-Ting TSAI, Miao-Li County (TW); Po-Hsin LIN, Miao-Li County (TW); Yu-Tsung LIU, Miao-Li County (TW); I-An YAO, Miao-Li County (TW)

(21) Appl. No.: 19/064,167

(22) Filed: Feb. 26, 2025

(30) Foreign Application Priority Data
Mar. 22, 2024 (CN) 202410333628.7

(51) Int. Cl. H10D 86/01; H10D 86/40; H10D 86/60

(52) U.S. Cl. CPC H10D 86/0241; H10D 86/441; H10D 86/60

(57) ABSTRACT

An electronic printing device and a method for manufacturing a metal printed object using the same are provided. The electronic printing device includes a printing substrate including: a substrate having an active region and a peripheral region; a power layer disposed on the substrate; an insulating layer disposed on the power layer; and a plurality of printing units disposed on the substrate and in the active region, wherein one of the plurality of printing units includes: a conductive layer disposed on the power layer and electrically connected to the power layer, wherein the insulating layer has a first opening, a first part of the conductive layer is covered by the insulating layer, a second part of the conductive layer is exposed by the first opening, the first part has a first thickness, the second has a second thickness, and the first thickness is greater than the second thickness.

### CROSS-REFERENCE TO RELATED APPLICATIONS

This application claims the benefits of the Chinese Patent Application Serial Number 202410333628.7, filed on Mar. 22, 2024, the subject matter of which is incorporated herein by reference.

### BACKGROUND

### Field

The present disclosure relates to an electronic printing device and a method for manufacturing a metal printed object using the same and, more specifically, the electronic printing device is a printing substrate with a special design.

### Description of Related Art

In recent years, 3D printing technology has gradually matured and has been used to prepare various items. 3D printing technology has the advantages of shortening production time, high accuracy of items, and the ability to have complex structures. In addition, because 3D printed items can be formed in one piece, it has the advantages of saving costs, saving assembly time, or improving the strength of the item.

However, metal 3D printing technology is limited by expensive machine parts and strict specifications of metal powders, which greatly reduces the market potential and its related applications. In addition, poor reliability of the printing substrate is not conducive to item production.

Therefore, it is desirable to provide a device and a method for manufacturing a metal printed object to improve the aforesaid defects.

### SUMMARY

The present disclosure provides an electronic printing device, comprising a printing substrate, wherein the printing substrate comprises: a substrate having an active region and a peripheral region, wherein the active region is adjacent to the peripheral region; a power layer disposed on the substrate; an insulating layer disposed on the power layer; and a plurality of printing units disposed on the substrate and disposed in the active region, wherein one of the plurality of printing units comprises: a conductive layer disposed on the power layer and electrically connected to the power layer, wherein the insulating layer has a first opening, a first part of the conductive layer is covered by the insulating layer, and a second part of the conductive layer is exposed by the first opening, wherein the first part of the conductive layer has a first thickness, the second part of the conductive layer has a second thickness, and the first thickness is greater than the second thickness.

The present disclosure further provides a method for manufacturing a metal printed object, comprising: providing the aforesaid electronic printing device; providing a first electrical energy to a first group of printing units among the plurality of printing units of the printing substrate to perform a first printing, thereby printing the metal in the electrolyte on the cathode plate to form a first part of the metal printed object; and providing a second electrical energy to a second group of printing units among the plurality of printing units of the printing substrate to perform a second printing, thereby printing the metal in the electrolyte on the cathode plate to form a second part on the metal printed object, wherein the second part is formed on the first part.

Other novel features of the disclosure will become more apparent from the following detailed description when taken in conjunction with the accompanying drawings.

### BRIEF DESCRIPTION OF DRAWINGS

FIG. 1 is a schematic view of an electronic printing device according to one embodiment of the present disclosure.

FIG. 2 is a top schematic view of a printing substrate according to one embodiment of the present disclosure.

FIG. 3A to FIG. 3D are schematic views showing a method for manufacturing a printing substrate according to one embodiment of the present disclosure.

FIG. 4 is a cross-sectional schematic view of a printing substrate according to one embodiment of the present disclosure.

FIG. 5 is a cross-sectional schematic view of a printing substrate according to another embodiment of the present disclosure.

FIG. 6A and FIG. 6B are top schematic views of a part of a driving layer and a power layer according to one embodiment of the present disclosure.

FIG. 7 is a schematic view showing an equivalent circuit of a printing element according to one embodiment of the present disclosure.

FIG. 8A to FIG. 8D are schematic views showing a method for manufacturing a printing substrate according to one embodiment of the present disclosure.

FIG. 9 is a cross-sectional schematic view of a printing substrate according to one embodiment of the present disclosure.

FIG. 10 is a cross-sectional schematic view of a printing substrate according to another embodiment of the present disclosure.

FIG. 11A and FIG. 11B are schematic views showing a method for manufacturing a metal printed object according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

In the present disclosure, the thickness can be measured by using an optical microscope or by a cross-sectional image obtained by an electron microscope, but the present disclosure is not limited thereto. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

It should be noted that the technical solutions provided in different embodiments below can be replaced, combined or mixed with each other to constitute another embodiment without violating the spirit of the present disclosure.

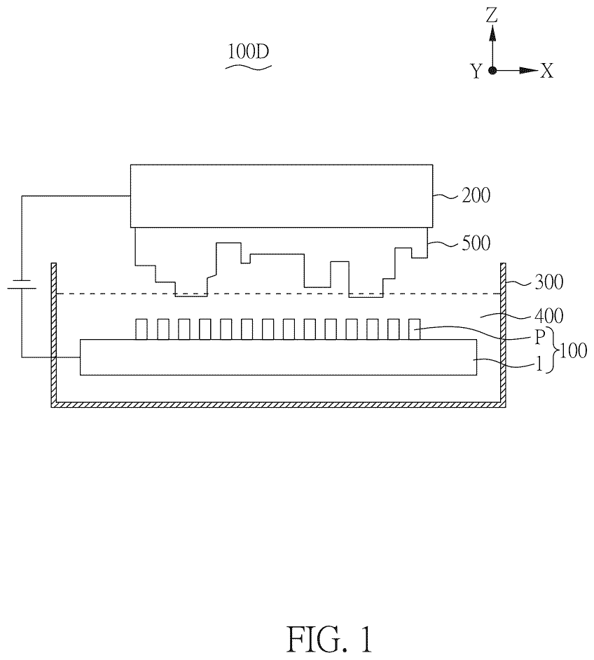

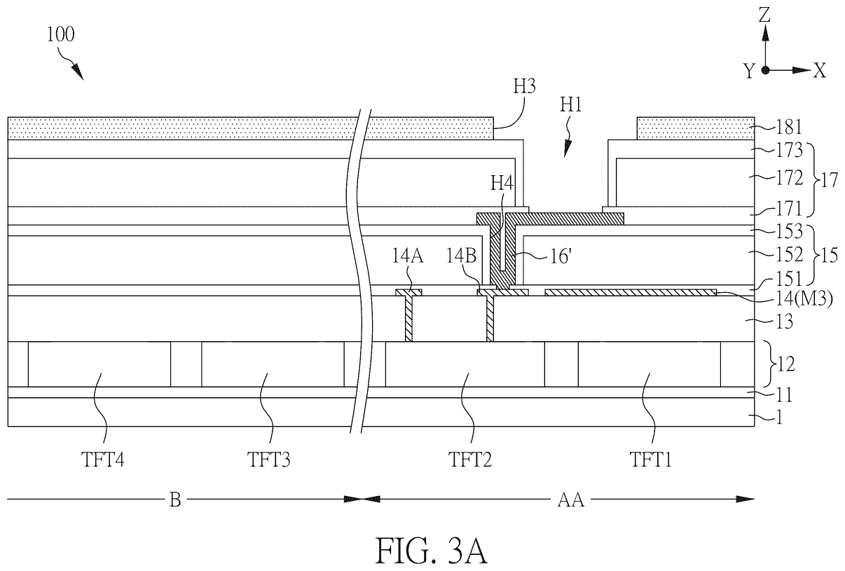

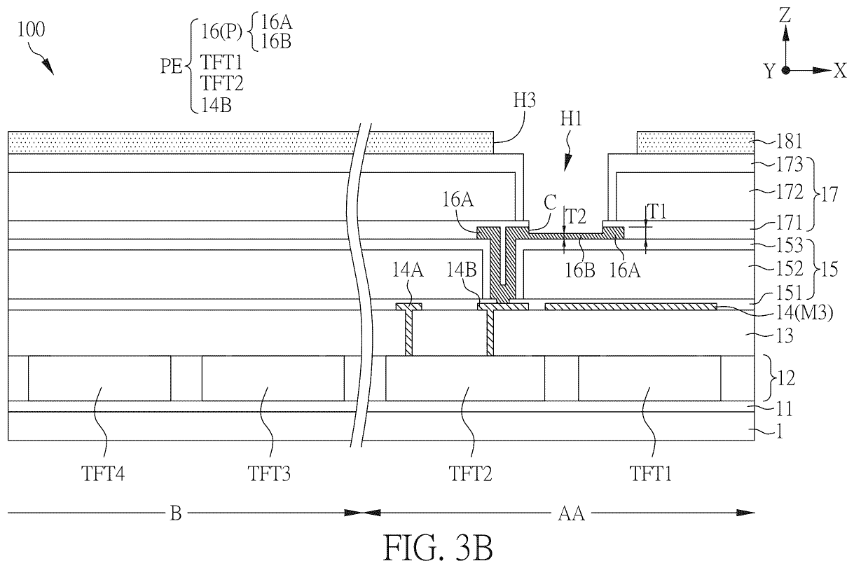

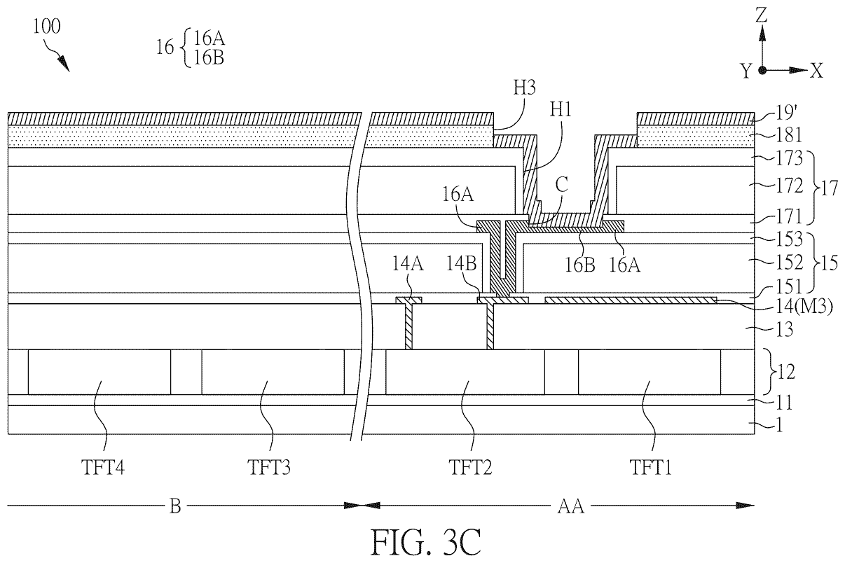

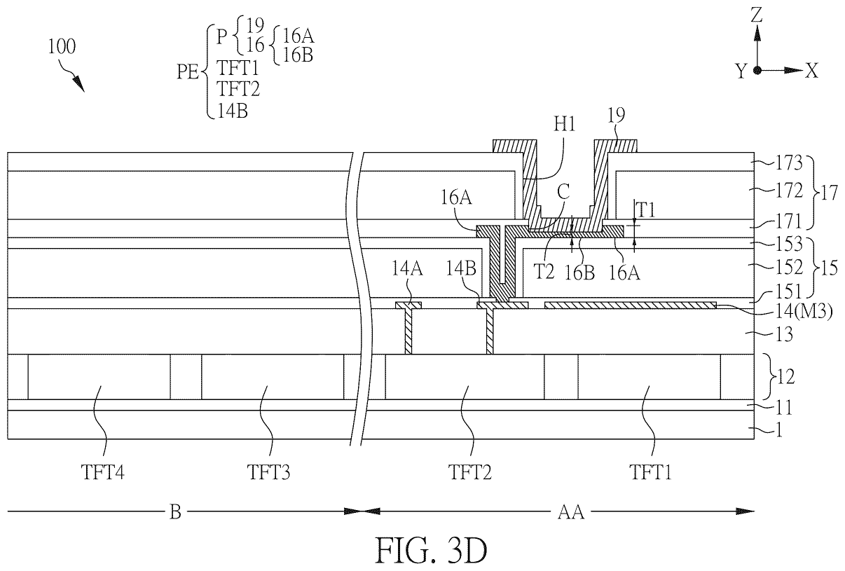

FIG. 1 is a schematic view of an electronic printing device according to one embodiment of the present disclosure. FIG. 3D is a cross-sectional schematic view of a printing substrate according to one embodiment of the present disclosure.

In one embodiment of the present disclosure, as shown in FIG. 1, the electronic printing device 100D may comprise a printing substrate 100. As shown in FIG. 3D, the printing substrate 100 comprises a substrate 1, a power layer 14, an insulating layer 17 and a plurality of printing units P. The substrate 1 has an active region AA and a peripheral region B, and the active region AA is adjacent to the peripheral region B. The power layer 14 is disposed on the substrate 1, and the insulating layer 17 is disposed on the power layer 14. The plurality of printing units P are disposed on the substrate 1 and locate in the active region AA. For convenience of explanation, only one printing unit P is shown in FIG. 3D. The printing unit P comprises a conductive layer 16 disposed on the power layer 14 and electrically connected to the power layer 14. The insulating layer 17 has a first opening H1, a first part 16A of the conductive layer 16 is covered by the insulating layer 17, and a second part 16B of the conductive layer 16 is exposed by the first opening H1. The first part 16A of the conductive layer 16 has a first thickness T1, the second part 16B of the conductive layer 16 has a second thickness T2, and the first thickness T1 is greater than the second thickness T2. The measurement direction of the thickness can be measured along the normal direction Z of the substrate 1 (which can be called the third direction). In one embodiment of the present disclosure, each of the printing units P may have the structure shown in FIG. 3D and is not described again here.

In one embodiment of the present disclosure, as shown in FIG. 1, the electronic printing device 100D may comprise: a printing substrate 100; a cathode plate 200 disposed opposite to the printing substrate 100; and a tank 300 and an electrolyte 400, wherein the printing substrate 100 and the electrolyte 400 are disposed in the tank 300. When providing an electrical energy to the printing substrate 100 and the cathode plate 200, the metal ions in the electrolyte 400 will receive electrons, and the metal is deposited or printed on the cathode plate 200 to form a metal printed object 500. Through the electrochemical method, metal printed objects can be prepared in large quantities at the same time, thereby reducing production costs. According to some embodiments, the electrical energy may be voltage, current, or a combination thereof.

In one embodiment of the present disclosure, as shown in FIG. 1, the printing substrate 100 may comprise a plurality of printing units P disposed on the substrate 1. The components included in the printing substrate 100 are simplified in FIG. 1. The structure of the printing substrate and the manufacturing method thereof of the present disclosure will be described in detail below.

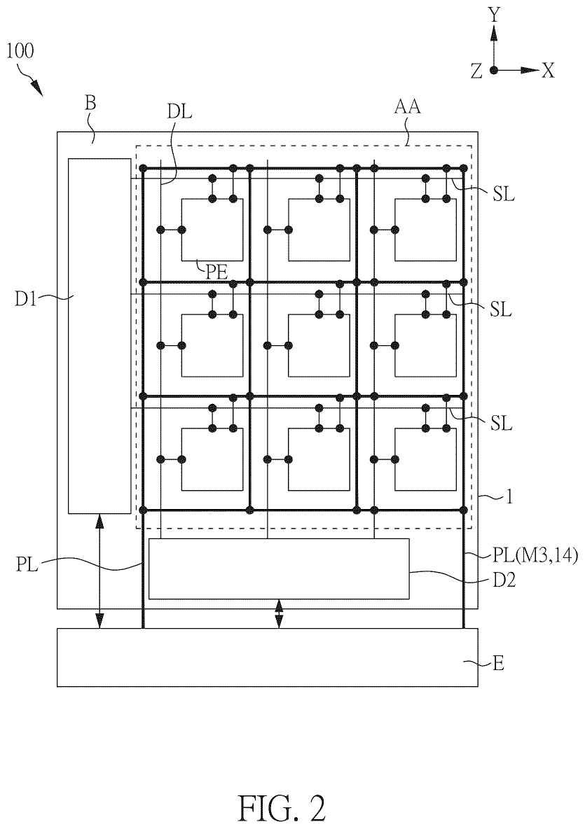

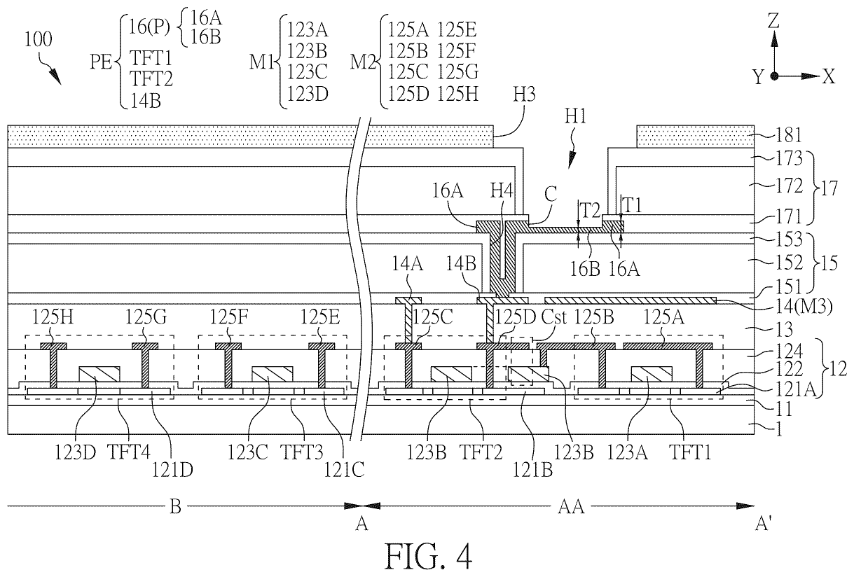

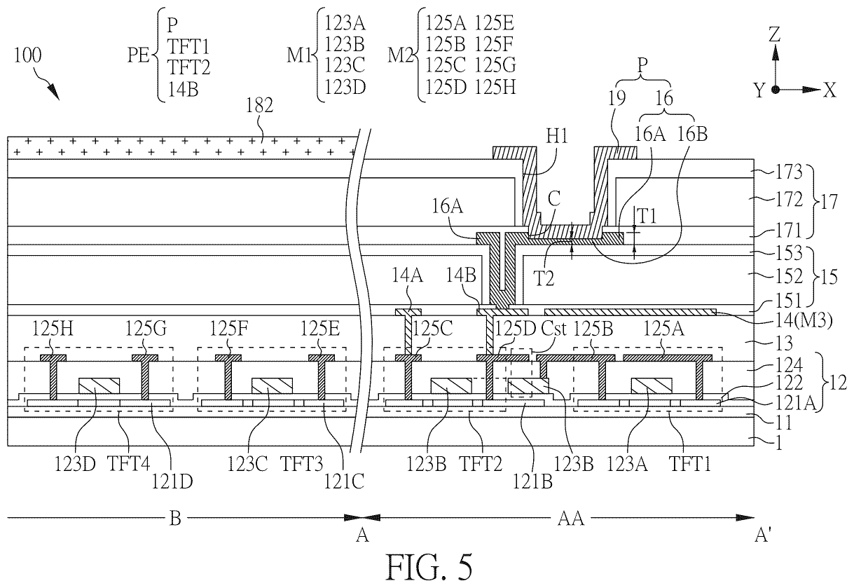

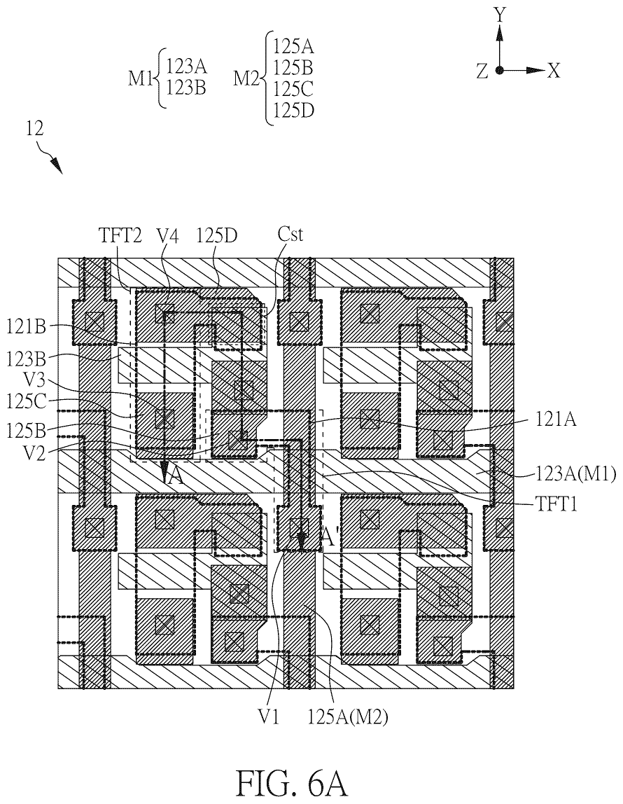

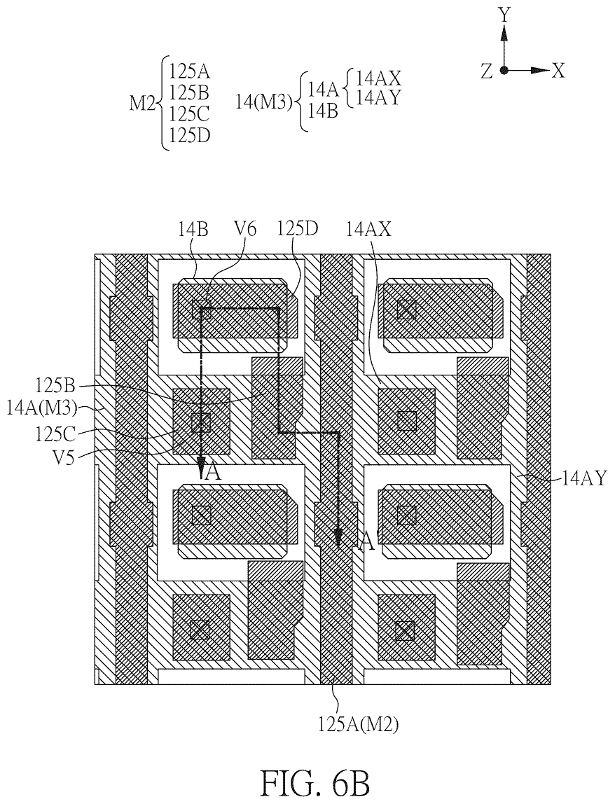

FIG. 2 is a top schematic view of a printing substrate according to one embodiment of the present disclosure. FIG. 3A to FIG. 3D are schematic views showing a method for manufacturing a printing substrate according to one embodiment of the present disclosure. FIG. 4 is a cross-sectional schematic view of a printing substrate according to one embodiment of the present disclosure. FIG. 5 is a cross-sectional schematic view of a printing substrate according to another embodiment of the present disclosure. FIG. 6A and FIG. 6B are top schematic views of a part of a driving layer and a power layer according to one embodiment of the present disclosure. Herein, FIG. 6A and FIG. 6B are top schematic views of the same area, and for convenience of explanation, some components are omitted in FIG. 6A and FIG. 6B respectively.

In one embodiment of the present disclosure, as shown in FIG. 2, the printing substrate 100 may comprise: a substrate 1 having an active region AA and a peripheral region B, wherein the active region AA is adjacent to the peripheral region B; a plurality of printing elements PE respectively disposed on the substrate 1 and locating in the active region AA; and a first driving unit D1 and a second driving unit D2 respectively disposed on the substrate 1 and locating in the peripheral region B. The first driving unit D1 and the second driving unit D2 are electrically connected to the printing element PE respectively. As shown in FIG. 3D, the printing substrate 100 further comprises a driving layer 12 disposed on the substrate 1, wherein the power layer 14 is disposed on the driving layer 12 and electrically connected to the driving layer 12. One printing element PE is used for explanation. One printing element PE may comprise a printing unit P, a part of the driving layer 12 and a part of the power layer 14. The printing unit P may comprise the conductive layer 16. According to some embodiments, the printing unit P may comprise the conductive layer 16 and the anode 19, and the conductive layer 16 may be electrically connected to the anode 19. According to some embodiments, another part of the power layer 14 (for example, the first part 14A shown in FIG. 6B) may be used as a power line PL.

In one embodiment of the present disclosure, as shown in FIG. 2, the printing substrate 100 may comprise a first driving unit D1 and a scan line SL. More specifically, the first driving unit D1 may be, for example, electrically connected to one of the printing elements PE through the scan line SL. The printing substrate 100 may comprise a second driving unit D2 and a data line DL. More specifically, the second driving unit D2 may be, for example, electrically connected to one of the printing elements PE through the data line DL. By controlling the first driving unit D1 and the second driving unit D2, the signals may be transmitted to the printing elements PE through the scan line SL and the data line DL, thereby applying electrical energy to the printing unit P of the printing element PE (for example, as shown in FIG. 3D) to perform the printing by the printing substrate 100. The printing substrate 100 may comprise a plurality of scan lines SL and a plurality of data lines DL. The scan line SL may extend along a first direction (for example, the X direction), and the data line DL may extend along a second direction (for example, the Y direction). The first direction and the second direction may be different and, for example, the first direction may be perpendicular to the second direction. The first direction may be perpendicular to a third direction (for example, the normal direction Z of the substrate 1), and the second direction may be perpendicular to the third direction (for example, the normal direction Z of the substrate 1). In one embodiment of the present disclosure, as shown in FIG. 2, the active region AA may be, for example, disposed surrounding the peripheral region B; but the present disclosure is not limited thereto. It should be noted that, one first driving unit D1 and one second driving unit D2 are used as an example in the figure, but in other embodiments of the present disclosure, the printing substrate 100 may comprise a plurality of first driving units D1 and/or a plurality of second driving units D2, and the first driving units D1 and/or the second driving units D2 are electrically connected to one of the printing elements PE respectively. According to some embodiments, the first driving unit D1 and the second driving unit D2 may not be disposed on the substrate 1.

In one embodiment of the present disclosure, as shown in FIG. 2, the printing substrate 100 may comprise an electronic component E, wherein the electronic component E may be electrically connected to the first driving unit D1 and the second driving unit D2 respectively. The electronic component E may be used, for example, to control or receive the signals transmitting to the first driving unit D1 and/or the second driving unit D2. In addition, the electronic component E may be electrically connected to one of the printing elements PE through the power line PL to transmit the electrical energy to the printing element PE. In the present disclosure, the electronic component E may be, for example, an integrated circuit (IC); but the present disclosure is not limited thereto. In one embodiment of the present disclosure, as shown in FIG. 2, the power line PL may be designed in a grid shape and electrically connected to a plurality of printing elements PE through parallel connection to reduce the impedance of the conductive lines.

In one embodiment of the present disclosure, as shown in FIG. 3A, the method for manufacturing the printing substrate 100 may comprise: providing a substrate 1; forming a buffer layer 11, a driving layer 12, an insulating layer 13, a third metal layer M3, another insulating layer 15, a conductive layer 16′ and an insulating layer 17 on the substrate 1 in sequence. Herein, the third metal layer M3 may comprise the power layer 14. The power layer 14 shown in the cross-sectional view of FIG. 3A may comprise the power line PL shown in the top view of FIG. 2. More specifically, the power layer 14 may comprise a first part 14A and a second part 14B, and the first part 14A and the second part 14B are electrically connected to the second transistor TFT2 respectively. Herein, the power line PL shown in the top view of FIG. 2 may be the first part 14A of the power layer 14. The driving layer 12 may comprise: a first transistor TFT1 and a second transistor TFT2 respectively disposed in the active region AA; and a third transistor TFT3 and a fourth transistor TFT4 respectively disposed in the peripheral region B. The first transistor TFT1 may be electrically connected to the second transistor TFT2, and the second transistor TFT2 may be electrically connected to the power layer 14. The conductive layer 16′ may be electrically connected to the power layer 14 through the opening H4 of the insulating layer 15. FIG. 3A simply shows the transistor as a block, and a more detailed structure of the transistor will be illustrated below. The insulating layer (comprising the insulating layer 13, the insulating layer 15 and the insulating layer 17) described in the present disclosure may be single layer or multi-layer, but the present disclosure is not limited thereto.

Next, the insulating layer 17 is patterned to form the first opening H1, wherein the first opening H1 exposes the surface of a part of the conductive layer 16′. Then, a first protection layer 181 is formed on the insulating layer 17, wherein the first protection layer 181 has a third opening H3, and the third opening H3 is connected to the first opening H1. In other embodiments of the present disclosure, the first protection layer 181 can be first formed on the insulating layer 17, followed by patterning the insulating layer 17 to form the first opening H1, wherein the first opening H1 exposes the surface of a part of the conductive layer 16′, the first protection layer 181 has a third opening H3, and the third opening H3 is connected to the first opening H1. According to some embodiments, the insulating layer 17 (for example, the first insulating layer 171) may be patterned by using an etching gas, while the etching gas may react with the surface of a portion of the conductive layer 16′ to produce undesirable by-products.

Next, as shown in FIG. 3B, the conductive layer 16′ is etched to form a concave C, thereby forming the conductive layer 16, that is, the upper portion of the conductive layer 16′ in FIG. 3A can be removed. Herein, the first opening H1 of the insulating layer 17 is connected to the concave C of the conductive layer 16 to expose a part of the conductive layer 16. More specifically, the conductive layer 16 comprises a first part 16A and a second part 16B, and the first part 16A is connected to the second part 16B. Herein, the first part 16A of the conductive layer 16 is covered by the insulating layer 17, and the second part 16B of the conductive layer 16 is exposed by the first opening H1, thereby forming the printing substrate 100 shown in FIG. 4. According to some embodiments, the first part 16A and the second part 16B refer to the portion of the conductive layer 16 on the insulating layer 15. According to some embodiments, the first thickness T1 of the first part 16A and the second thickness T2 of the second part 16B may be measured by using the upper surface of the insulating layer 15 as the reference plane. When the upper surface of the insulating layer 15 is not a plane surface, in a cross-sectional view, the first thickness T1 and the second thickness T2 may be measured by using a virtual line (not shown in the figure) parallel to the first direction X on the insulating layer 15 as the reference line. In the present embodiment, the by-product formed on the surface of the conductive layer 16′ during the aforesaid patterning of the insulating layer 17 may be removed by etching a part of the conductive layer 16′ to form the conductive layer 16. By removing the upper portion of the conductive layer 16′, the by-product formed on the surface of the conductive layer 16′ can be removed. Therefore, the defects caused by the by-products generated by the conductive layer 16′ can be improved, and the reliability or yield of the printing substrate 100 can be improved.

In the present embodiment, as shown in FIG. 3B, the first part 16A of the conductive layer 16 has a first thickness T1, the second part 16B of the conductive layer 16 has a second thickness T2, and the first thickness T1 is greater than the second thickness T2. In the present embodiment, the printing unit P may comprise a conductive layer 16; but the present disclosure is not limited thereto. In the present embodiment, the printing unit P, the first transistor TFT1, the second transistor TFT2 and a part of the power layer 14 (for example, the second part 14B of the power layer 14) may together form the printing element PE. In one embodiment of the present disclosure, as shown in FIG. 2 to FIG. 3B, the first driving unit D1 may comprise a third transistor TFT3, and the second driving unit D2 may comprise a fourth transistor TFT4. By controlling the first driving unit D1 (for example, the third transistor TFT3) and the second driving unit D2 (for example, the fourth transistor TFT4), the signals can be transmitted to the printing element PE through the scan line SL and the data line DL, thereby applying an electrical energy to the printing unit P. It should be noted that, one third transistor TFT3 and one fourth transistor TFT4 are used as an example in the figure; but in other embodiments of the present disclosure, the first driving unit D1 and the second driving unit D2 may respectively comprise a plurality of third transistors TFT3 and/or a plurality of fourth transistors TFT4.

Next, as shown in FIG. 3C, a conductive layer 19′ may be further formed on the first protection layer 181 and the insulating layer 17 and in the first opening H1 of the insulating layer 17 and the concave C of the conductive layer 16. Herein, a part of the conductive layer 19′ may be disposed on the second part 16B of the conductive layer 16 and in contact with the second part 16B of the conductive layer 16. Then, as shown in FIG. 3D, the first protection layer 181 and a part of the conductive layer 19′ are removed to form an anode 19, wherein the anode 19 may be disposed on the second part 16B of the conductive layer 16, and a part of the anode 19 may be in contact with the second part 16B of the conductive layer 16. Then, a second protection layer 182 may be formed on the insulating layer 17 (as shown in FIG. 5), and the second protection layer 182 is disposed in the peripheral region B, thereby forming the printing substrate 100, for example, as shown in FIG. 5. In the present disclosure, the material of the conductive layer 19′ may be referred to that of the anode 19, and is not described again here. In the present embodiment, the printing unit P may comprise a conductive layer 16 and an anode 19; but the present disclosure is not limited thereto. In the present embodiment, the printing unit P, the first transistor TFT1, the second transistor TFT2 and a part of the power layer 14 (for example, the second part 14B of the power layer 14) may together form the printing element PE.

In the present disclosure, the method for forming the buffer layer 11, the driving layer 12, the insulating layer 13, the power layer 14, another insulating layer 15, the conductive layer 16′, the insulating layer 17, the first protection layer 181, the second protection layer 182 and the conductive layer 19′ may respectively comprise chemical vapor deposition, physical vapor deposition, sputtering, coating or a combination thereof; but the present disclosure is not limited thereto. The “coating” may be, for example, dip coating, spin coating, roller coating, blade coating, spray coating or a combination thereof; but the present disclosure is not limited thereto. In addition, the method for forming the driving layer 12 may further comprise a patterning step. In the present disclosure, any suitable method may be used for patterning, for example, may comprise lithography and etching. Herein, the etching may comprise dry etching, wet etching or a combination thereof; but the present disclosure is not limited thereto. In the present disclosure, a suitable method may be used to remove the first protection layer 181 and a part of the conductive layer 19′ and, for example, the first protection layer 181 together with the conductive layer 19′ may be peeled off by external force; but the present disclosure is not limited thereto.

In the above FIG. 3A to FIG. 3D, a simplified transistor is used for illustration. In one embodiment of the present disclosure, the more detailed transistor structure is illustrated in FIG. 4 and FIG. 5 below. As shown in FIG. 4, the printing substrate 100 may comprise: a substrate 1 having an active region AA and a peripheral region B, wherein the active region AA is adjacent to the peripheral region B; a power layer 14 disposed on the substrate 1; an insulating layer 17 disposed on the power layer 14; and a plurality of printing units P disposed on the substrate 1 and locating in the active region AA. Herein, as shown in FIG. 4, the printing unit P may comprise: a conductive layer 16 disposed on the power layer 14 and electrically connected to the power layer 14, wherein the conductive layer 16 has a concave C, wherein the insulating layer 17 is disposed on the conductive layer 16, the insulating layer 17 has a plurality of first openings H1, and one of the first openings H1 is connected to the concave C of the conductive layer 16 and exposes a part of the conductive layer 16. More specifically, the conductive layer 16 comprises a first part 16A and a second part 16B, and the first part 16A is connected to the second part 16B, wherein the first part 16A of the conductive layer 16 is covered by the insulating layer 17, and the second part 16B of the conductive layer 16 is exposed by the first opening H1.

In one embodiment of the present disclosure, as shown in FIG. 4, the printing substrate 100 may comprise a driving layer 12 disposed on the substrate 1 and locating in the active region AA and the peripheral region B, wherein the insulating layer 17 is disposed on the driving layer 12. In the present disclosure, the driving layer 12 may comprise a first transistor TFT1, a second transistor TFT2, a third transistor TFT3 and a fourth transistor TFT4, the first transistor TFT1 and the second transistor TFT2 may be respectively disposed in the active region AA, and the third transistor TFT3 and the fourth transistor TFT4 may be respectively disposed in the peripheral region B, wherein the first transistor TFT1 may be electrically connected to the second transistor TFT2, and the second transistor TFT2 may be electrically connected to the printing unit P and the power layer 14 respectively. The printing unit P, the first transistor TFT1, the second transistor TFT2 and a part of the power layer 14 can together form the printing element PE. By controlling the first transistor TFT1 and the second transistor TFT2, the electrical energy may be applied to different printing units P, thereby producing a patterned metal printed object such as a three-dimensional (3D) metal printed object.

In one embodiment of the present disclosure, as shown in FIG. 4, the driving layer 12 may comprise: a semiconductor layer disposed on the substrate 1, wherein the semiconductor layer may comprise a first semiconductor layer 121A, a second semiconductor layer 121B, a third semiconductor layer 121C and a fourth semiconductor layer 121D; a gate insulating layer 122 disposed on the semiconductor layer; a first metal layer M1 disposed on the gate insulating layer 122, wherein the first metal layer M1 may comprise a first gate electrode 123A, a second gate electrode 123B, a third gate electrode 123C and a fourth gate electrode 123D; an insulating layer 124 disposed on the first metal layer M1; a second metal layer M2 disposed on the insulating layer 124, wherein the second metal layer M2 may comprise a first source electrode 125A, a first drain electrode 125B, a second source electrode 125C, a second drain electrode 125D, a third source electrode 125E, a third drain electrode 125F, a fourth source electrode 125G and a fourth drain electrode 125H. The first transistor TFT1 may comprise: the first semiconductor layer 121A; the gate insulating layer 122; the first gate electrode 123A; the insulating layer 124; the first source electrode 125A; and the first drain electrode 125B, wherein the first source electrode 125A and the first drain electrode 125B are electrically connected to the first semiconductor layer 121A respectively. The second transistor TFT2 may comprise: the second semiconductor layer 121B; the gate insulating layer 122; the second gate electrode 123B; the insulating layer 124; the second source electrode 125C; and the second drain electrode 125D, wherein the second source electrode 125C and the second drain electrode 125D are electrically connected to the second semiconductor layer 121B respectively. The third transistor TFT3 may comprise: the third semiconductor layer 121C; the gate insulating layer 122; the third gate electrode 123C; the insulating layer 124; the third source electrode 125E; and the third drain electrode 125F, wherein the third source electrode 125E and the third drain electrode 125F are electrically connected to the third semiconductor layer 121C respectively. The fourth transistor TFT4 may comprise: the fourth semiconductor layer 121D; the gate insulating layer 122; the fourth gate electrode 123D; the insulating layer 124; the fourth source electrode 125G; and the fourth drain electrode 125H, wherein the fourth source electrode 125G and the fourth drain electrode 125H are electrically connected to the fourth semiconductor layer 121D respectively. It should be noted that, the structures of the first transistor TFT1, the second transistor TFT2, the third transistor TFT3 and the fourth transistor TFT4 in the figures are used as an example, and may be adjusted to other laminated transistors (such as bottom gate, double gate or dual gate transistors) according to the needs. In one embodiment of the present disclosure, as shown in FIG. 4, the first drain electrode 125B may extend outside and electrically connected to the second gate electrode 123B through a via, wherein the dash lines between the second gate electrodes 123B represents that the second gate electrodes 123B are electrically connected in another cross-sectional view. In one embodiment of the present disclosure, as shown in FIG. 2 and FIG. 4, the first gate electrode 123A may be electrically connected to the scan line SL, the first source electrode 125A may be electrically connected to the data line DL, thereby transmitting signals to the printing element PE.

The transistor in FIG. 4 mentioned above is a top gate transistor as an example. According to other embodiments, a bottom gate transistor can also be applied to the present disclosure, which will not be described again here. Other types of transistors are also applicable to the present disclosure and will not be described again.

In the present disclosure, the substrate 1 may be a flexible substrate or a rigid substrate, but the present disclosure is not limited thereto. The substrate 1 may be single layer or multi-layer, but the present disclosure is not limited thereto. The material of the substrate 1 may be glass, quartz, sapphire, ceramics, plastic, polycarbonate (PC), polyimide (PI), polypropylene (PP), polyethylene terephthalate (PET), polymethylmethacrylate (PMMA), other suitable materials or a combination thereof; but the present disclosure is not limited thereto. In the present disclosure, the materials of the first semiconductor layer 121A, the second semiconductor layer 121B, the third semiconductor layer 121C and the fourth semiconductor layer 121D may respectively comprise amorphous silicon, polycrystalline silicon (such as low-temperature polycrystalline silicon (LTPS)), or an oxide semiconductor (such as indium gallium zinc oxide (IGZO) or indium gallium oxide (IGO)); but the present disclosure is not limited thereto. In addition, the third semiconductor layer 121C and the fourth semiconductor layer 121D may respectively comprise a doping carrier, such as N-type carrier or P-type carrier. In one embodiment of the present disclosure, the doping carrier of the third semiconductor layer 121C may be different from the doping carrier of the fourth semiconductor layer 121D; and for example, the third semiconductor layer 121C may comprise N-type carriers to form a N-doping semiconductor layer and the fourth semiconductor layer 121D may comprise P-type carriers to form a P-doping semiconductor layer; but the present disclosure is not limited thereto. In the present disclosure, the materials of the gate insulating layer 122 and the insulating layer 124 may respectively comprise silicon nitride, silicon oxide, silicon oxynitride, silicon carbonitride, aluminum oxide, or a combination thereof; but the present disclosure is not limited thereto. In the present disclosure, the materials of the first gate electrode 123A, the second gate electrode 123B, the third gate electrode 123C, the fourth gate electrode 123D, the first source electrode 125A, the first drain electrode 125B, the second source electrode 125C, the second drain electrode 125D, the third source electrode 125E, the third drain electrode 125F, the fourth source electrode 125G and the fourth drain electrode 125H may respectively comprise a metal, a metal oxide, an alloy thereof, or a combination thereof, and for example, may be gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO); but the present disclosure is not limited thereto.

In one embodiment of the present disclosure, as shown in FIG. 4, the power layer 14 may be disposed on the driving layer 12 and electrically connected to the driving layer 12. More specifically, the power layer 14 may comprise a first part 14A and a second part 14B, the first part 14A may be electrically connected to the second source electrode 125C of the second transistor TFT2, and the second part 14B may be electrically connected to the second drain electrode 125D of the second transistor TFT2 and the conductive layer 16 respectively. In one embodiment of the present disclosure, as shown in FIG. 2 and FIG. 4, the first part 14A of the power layer 14 may be electrically connected to the power line PL, thereby transmitting the electrical energy to the printing element PE. According to some embodiments, the first part 14A of the power layer 14 may form the power line PL. In one embodiment of the present disclosure, the first part 14A of the power layer 14 may be used as the power line PL. The printing unit P, the first transistor TFT1, the second transistor TFT2 and the second part 14B of the power layer 14 may together form the printing element PE. In the present disclosure, the material of the power layer 14 may comprise a metal, a metal oxide, an alloy thereof, or a combination thereof, and for example, may be gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO); but the present disclosure is not limited thereto.

In one embodiment of the present disclosure, as shown in FIG. 4, the insulating layer 17 may comprise a first insulating layer 171, a second insulating layer 172 and a third insulating layer 173, and the second insulating layer 172 is disposed between the first insulating layer 171 and the third insulating layer 173, wherein the via of the first insulating layer 171 is connected to the via of the third insulating layer 173 to form the first opening H1 of the insulating layer 17. In the present disclosure, the materials of the first insulating layer 171 and the third insulating layer 173 may respectively comprise an inorganic material, and suitable inorganic material may be, for example, silicon nitride, silicon oxide, silicon oxynitride, silicon carbonitride, aluminum oxide, or a combination thereof; but the present disclosure is not limited thereto. The material of the second insulating layer 172 may comprise an organic material, and suitable organic material may be, for example, polycarbonate (PC), polyimide (PI), polypropylene (PP), polyethylene terephthalate (PET), polybenzoxazole (PBO), benzocyclobutene (ECB), polyfluoroalkoxy (PFA), epoxy resin, photoresist, polymer, or a combination thereof; but the present disclosure is not limited thereto. Through the above design of the insulating layer 17, it can prevent air and/or moisture from entering the printing substrate 100 and improve the reliability of the printing substrate 100.

In one embodiment of the present disclosure, as shown in FIG. 4, the printing substrate 100 may comprise another insulating layer 15 disposed on the power layer 14, wherein the insulating layer 15 comprises an opening H4, and the conductive layer 16 may be disposed on the insulating layer 15 and in the opening H4 and electrically connected to the second part 14B of the power layer 14 through the opening H4. More specifically, the insulating layer 15 may comprise a fourth insulating layer 151, a fifth insulating layer 152 and a sixth insulating layer 153, and the fifth insulating layer 152 is disposed between the fourth insulating layer 151 and the sixth insulating layer 153, wherein the via of the fourth insulating layer 151 is connected to the via of the sixth insulating layer 153 to form the opening H4 of the insulating layer 15. In one embodiment of the present disclosure, as shown in FIG. 4, the insulating layer 15 may be disposed between the insulating layer 17 and the driving layer 12. In the present disclosure, the materials of the fourth insulating layer 151 and the sixth insulating layer 153 may respectively comprise an inorganic material, and the material of the fifth insulating layer 152 may comprise an organic material, wherein suitable inorganic material and suitable organic material may be referred to above and are not described again here. Through the above design of the insulating layer 15, it can prevent air and/or moisture from entering the printing substrate 100 and improve the reliability of the printing substrate 100.

In one embodiment of the present disclosure, as shown in FIG. 4, the conductive layer 16 has a first thickness T1, and the conductive layer 16 has a second thickness T2 at the concave C. More specifically, the first part 16A of the conductive layer 16 has the first thickness T1, and the second part 16B of the conductive layer 16 has the second thickness T2, wherein the first thickness T1 is greater than the second thickness T2. Herein, the “first thickness” refers to, for example, a distance between an upper surface of the first part 16A of the conductive layer 16 and an upper surface of the insulating layer 15 (for example, an upper surface of the sixth insulating layer 153) in the normal direction Z of the substrate 1; or refers to, for example, a distance between an upper surface of the conductive layer 16 covered by the insulating layer 17 and an upper surface of the insulating layer 15 (for example, the upper surface of the sixth insulating layer 153) in the normal direction Z of the substrate 1. The “second thickness” refers to, for example, a distance between an upper surface of the second part 16B of the conductive layer 16 and an upper surface of the insulating layer 15 (for example, an upper surface of the sixth insulating layer 153) in the normal direction Z of the substrate 1; or refers to, for example, a distance between an upper surface of the conductive layer 16 at the concave C and an upper surface of the insulating layer 15 (for example, an upper surface of the sixth insulating layer 153) in the normal direction Z of the substrate 1; or refers to, for example, a distance between an exposed upper surface of the conductive layer 16 and an upper surface of the insulating layer 15 (for example, an upper surface of the sixth insulating layer 153) in the normal direction Z of the substrate 1. In one embodiment of the present disclosure, a difference between the first thickness T1 and the second thickness T2 may be greater than or equal to 10 nm (T1−T2≥10 nm); but the present disclosure is not limited thereto. In one embodiment of the present disclosure, the difference between the first thickness T1 and the second thickness T2 may be greater than or equal to 5 nm (T1−T25≥5 nm) and, for example, the difference between the first thickness T1 and the second thickness T2 may be between 5 nm and 1000 nm, between 10 nm and 1000 nm, between 10 nm and 500 nm, between 10 nm and 200 nm, between 10 nm and 100 nm or between 10 nm and 50 nm; but the present disclosure is not limited thereto. In the present disclosure, the material of the conductive layer 16 may comprise titanium, molybdenum, gold, iridium, rhodium, palladium, an alloy thereof or a combination thereof; but the present disclosure is not limited thereto. According to some embodiments, the conductive layer 16 may comprise a metal oxide, such as indium tin oxide (ITO).

In one embodiment of the present disclosure, as shown in FIG. 4, the printing substrate 100 may comprise a buffer layer 11 disposed between the substrate 1 and the driving layer 12. In the present disclosure, the material of the buffer layer 11 may comprise silicon nitride, silicon oxide, silicon oxynitride, silicon carbonitride, or a combination thereof; but the present disclosure is not limited thereto. In one embodiment of the present disclosure, as shown in FIG. 4, the printing substrate 100 may comprise an insulating layer 13 disposed between the driving layer 12 and the power layer 14. In the present disclosure, the material of the insulating layer 13 may comprise silicon nitride, silicon oxide, silicon oxynitride, silicon carbonitride, aluminum oxide, or a combination thereof; but the present disclosure is not limited thereto.

In one embodiment of the present disclosure, as shown in FIG. 4, the printing substrate 100 may comprise a first protection layer 181 disposed on the insulating layer 17 and locating in the active region AA and the peripheral region B, wherein the first protection layer 181 has a plurality of third openings H3, and one of the third openings H3 is connected to one of the first openings H1. It should be noted that, one first opening H1 and one third opening H3 are shown in the figures as an example, but in another cross-sectional view, the insulating layer 17 may comprise a plurality of first openings H1, the first protection layer 181 may comprise a plurality of third openings H3, and the third openings H3 may be respectively connected to the first openings H1. In one embodiment of the present disclosure, in the normal direction Z of the substrate 1, a part of the third opening H3 may be overlapped with the concave C of the conductive layer 16. In one embodiment of the present disclosure, the projection area of the third opening H3 on the substrate 1 may be greater than the projection area of the first opening H1 on the substrate 1. In the present disclosure, the material of the first protection layer 181 may comprise epoxy resin, photoresist, polymer, or a combination thereof; but the present disclosure is not limited thereto.

In one embodiment of the present disclosure, the printing substrate may be referred to that shown in FIG. 5, wherein the printing substrate shown in FIG. 5 is similar to that shown in FIG. 4, except for the following differences. In the present embodiment, the printing substrate 100 may not comprise the first protection layer 181 shown in FIG. 4, and the printing substrate 100 may comprise a second protection layer 182 disposed on the insulating layer 17 and locating in the peripheral region B. More specifically, in the normal direction Z of the substrate 1, the second protection layer 182 may be overlapped with the first driving unit D1 (as shown in FIG. 2), the second driving unit D2 (as shown in FIG. 2) and/or the electronic component E (as shown in FIG. 2). Therefore, it is possible to avoid the direct contact of the above components with the electrolyte during the manufacturing process of the metal printed object, so the risk of damage to the above components can be reduced, thereby improving the reliability of the printing substrate 100. In the present disclosure, the material of the second protection layer 182 may comprise waterproof glue, glass glue, optical glue, silicone glue, hot melt glue, AB glue, light-curing glue, polymer glue, epoxy resin, photoresist, polymer, or a combination thereof; but the present disclosure is not limited thereto.

In one embodiment of the present disclosure, as shown in FIG. 5, the printing unit P may comprise: a conductive layer 16 disposed on the power layer 14 and electrically connected to the power layer 14 (for example, the second part 14B of the power layer 14), wherein the conductive layer 16 has a concave C; and an anode 19 disposed in one of the first openings H1 and the concave C, and in contact with the exposed part of the conductive layer 16. More specifically, the anode 19 may be disposed on the second part 16B of the conductive layer 16 and in contact with the second part 16B of the conductive layer 16. By applying an electrical energy to the anode 19 of the printing substrate 100, metal can be deposited/printed on the corresponding cathode plate near the anode 19 to which electrical energy is applied, thereby forming a metal printed object. In the present disclosure, the anode 19 may be an electrochemistry anode, and suitable material thereof comprises platinum (Pt), titanium (Ti), gold (Au), iridium (Ir), rhodium (Rh), palladium (Pd), iron (Fe), an alloy thereof or a combination thereof; but the present disclosure is not limited thereto. In the present embodiment, the transistor shown in FIG. 5 is a top gate transistor as an example. According to other embodiments, the bottom gate transistor may also be used in the present disclosure, and is not described again here.

In one embodiment of the present disclosure, the driving layer 12 and the power layer 14 shown in FIG. 4 and FIG. 5 may be, for example, those shown in FIG. 6A and FIG. 6B, and the cross-sectional views along the line A-A′ may be, for example, the active region AA shown in FIG. 4 and FIG. 5. It should be noted that, all the structures shown in the figures are only used as an example, and the disposition positions and shapes of the components may be adjusted according to the needs. In FIG. 6A and FIG. 6B, the corresponding cross-sectional views along the A-A′ may be referred to those shown in FIG. 4 and FIG. 5. For the convenience of illustration, only the semiconductor layer 121, the first metal layer M1 and the second metal layer M2 are shown in FIG. 6A, and only the second metal layer M2 and the third metal layer M3 are shown in FIG. 6B.

In one embodiment of the present disclosure, as shown in FIG. 4 to FIG. 6B, the driving layer 12 may comprise a first transistor TFT1 and a second transistor TFT2. The first transistor TFT1 comprises: a first semiconductor layer 121A, a first gate electrode 123A, a first source electrode 125A and a first drain electrode 125B, wherein the first source electrode 125A and the first drain electrode 125B are electrically connected to the first semiconductor layer 121A through the via V1 and the via V2 respectively. The second transistor TFT2 comprises: a second semiconductor layer 121B, a second gate electrode 123B, a second source electrode 125C and a second drain electrode 125D, wherein the second source electrode 125C and the second drain electrode 125D are electrically connected to the second semiconductor layer 121B through the via V3 and the via V4 respectively. The power layer 14 comprises a first part 14A and a second part 14B, wherein the first part 14A may be electrically connected to the second source electrode 125C through the via V5, and the second part 14B may be electrically connected to the second drain electrode 125D through the via V6. In addition, as shown in FIG. 4 and FIG. 6A, the second drain electrode 125D and the second gate electrode 123B are partially overlapped to form a capacitance Cst, wherein the overlapping portions of the second drain electrode 125D and the second gate electrode 123B may respectively serve as the first capacitance electrode and the second capacitance electrode of the capacitance Cst. In one embodiment of the present disclosure, as shown in FIG. 6B, the first part 14A of the power layer 14 may be used as the power line PL, so the first part 14A of the power layer 14 has a grid design in the normal direction Z of the printing substrate 100. More specifically, as shown in FIG. 6B, the first part 14A of the power layer 14 may comprise a plurality of sub-portions 14AX extending along the first direction (the X direction) and a plurality of sub-portions 14AY extending along the second direction (the Y direction). The sub-portions 14AX and the sub-portion 14AY may be arranged in a crisscross pattern to form a grid structure. As shown in FIG. 6B, the grid structure formed by the first part 14A of the power layer 14 (including the sub-portions 14AX and the sub-portions 14AY) may be corresponded to the grid power lines PL shown in FIG. 2. FIG. 2 is a simplified figure, which only simply display the relationship between the power lines PL and the printing elements PE. FIG. 6 is a more detailed figure, which display the structures of the first part 14A and the second part 14B of the power layer 14 in detail.

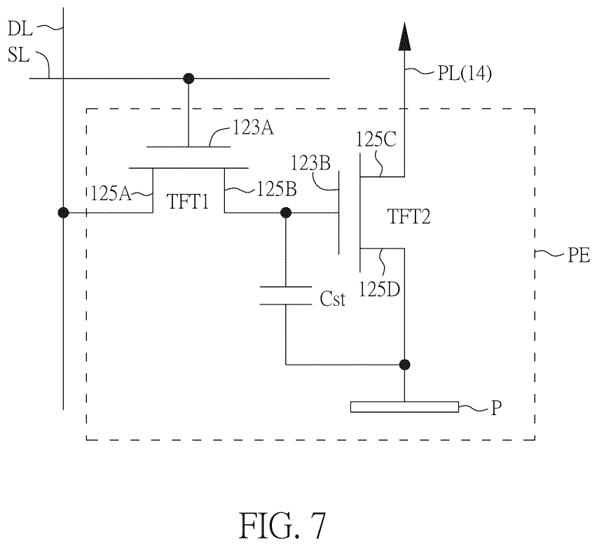

FIG. 7 is a schematic view showing an equivalent circuit of a printing element according to one embodiment of the present disclosure.

In one embodiment of the present disclosure, as shown in FIG. 7, the printing element PE may comprise: a first transistor TFT1 as a switch transistor (switch TFT), wherein signals of the scan line SL and the data line DL are respectively transmitted to the first transistor TFT1; a second transistor TFT2 as a driving transistor (driving TFT), wherein signals of the power line PL and the first transistor TFT1 are transmitted to the second transistor TFT2; and a capacitance Cst. Thus, the equivalent circuit shown in FIG. 7 is a 2T1C circuit. In one embodiment of the present disclosure, the capacitance Cst comprises: a first capacitance electrode; and a second capacitance electrode disposed opposite to the first capacitance electrode. More specifically, for example, as shown in FIG. 4 and FIG. 5, the second drain electrode 125D may extend outside and be used as the first capacitance electrode of the capacitance Cst. The second drain electrode 125D extending outside is partially overlapped with the second gate electrode 123B, and the region of the second gate electrode 123B overlapped with the second drain electrode 125D may be used as the second capacitance electrode of the capacitance Cst. In one embodiment of the present disclosure, as shown in FIG. 4, FIG. 5 and FIG. 7, the scan line SL may be electrically connected to the first gate electrode 123A, and the data line DL may be electrically connected to the first source electrode 125A to transmit signals to the first transistor TFT1. The printing element PE may comprise a printing unit P electrically connected to the second transistor TFT2. Herein, the power line PL may be electrically connected to the first part 14A of the power layer 14 to transmit signals to the second transistor TFT2, thereby driving the printing unit P.

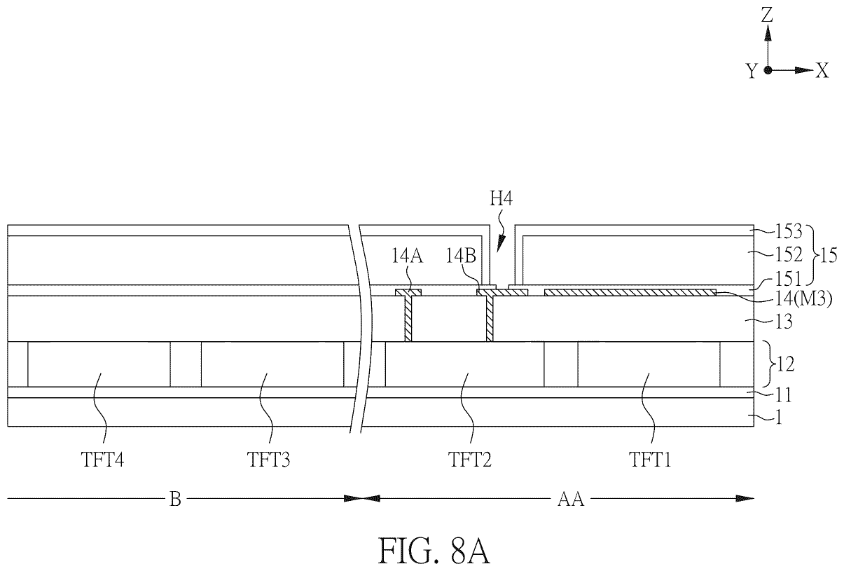

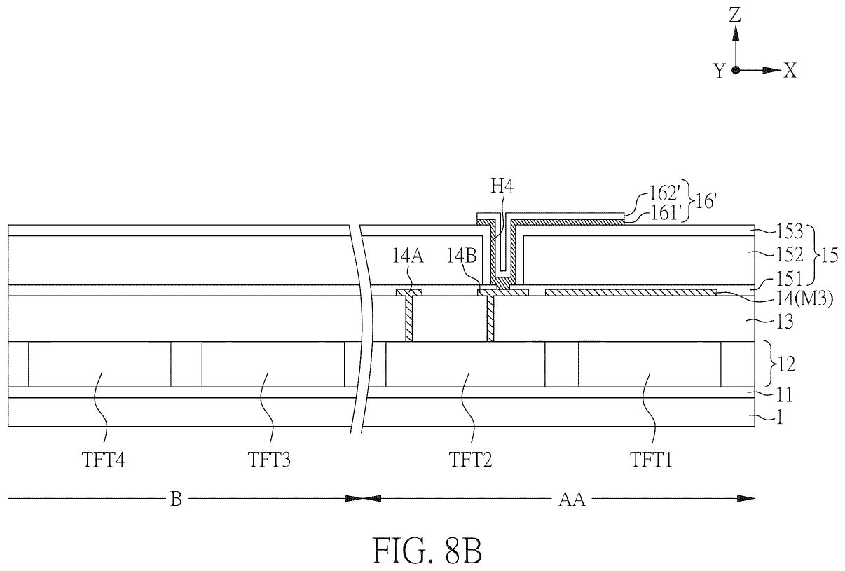

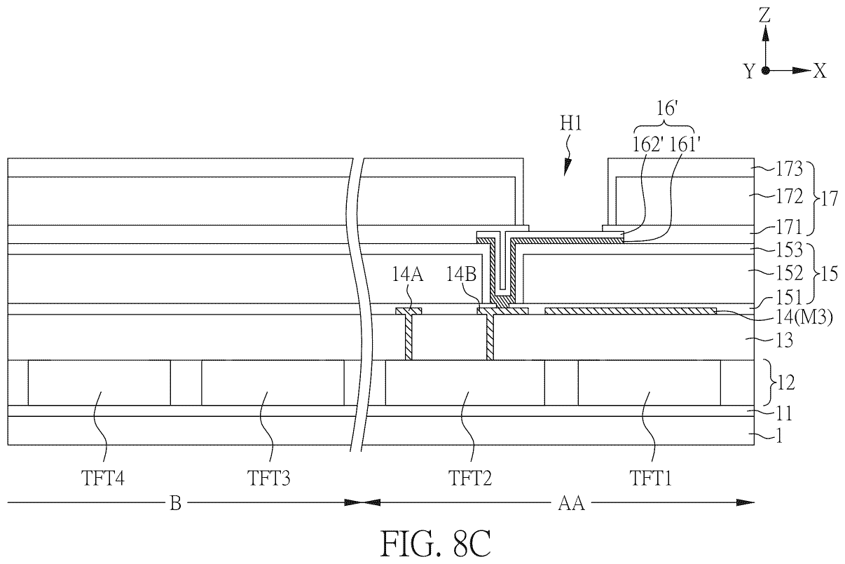

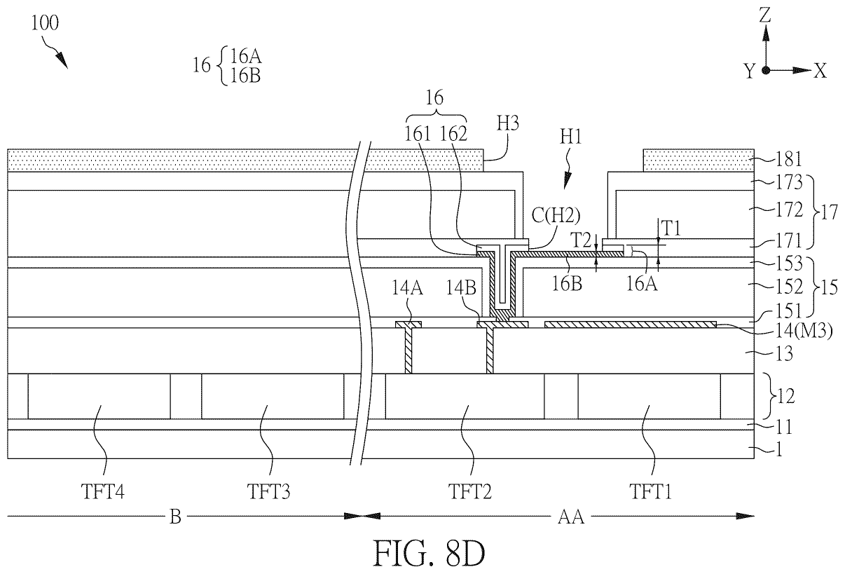

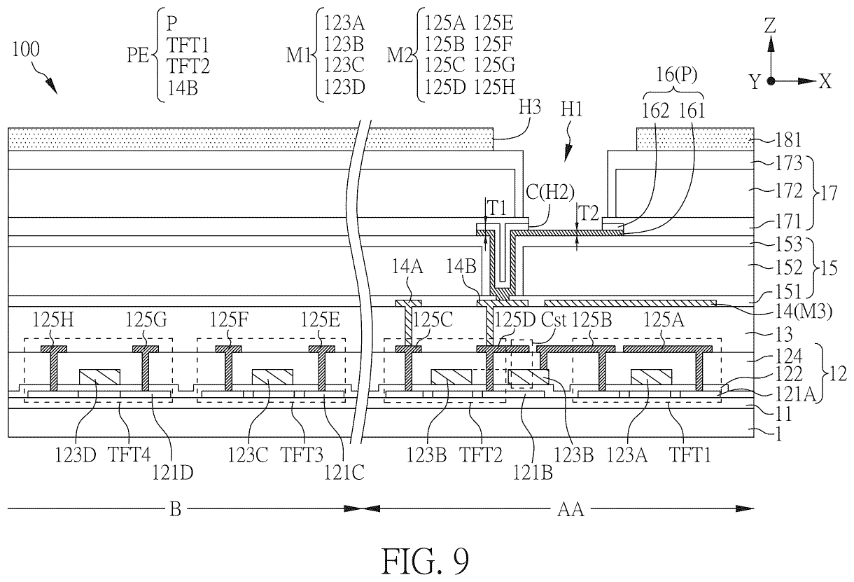

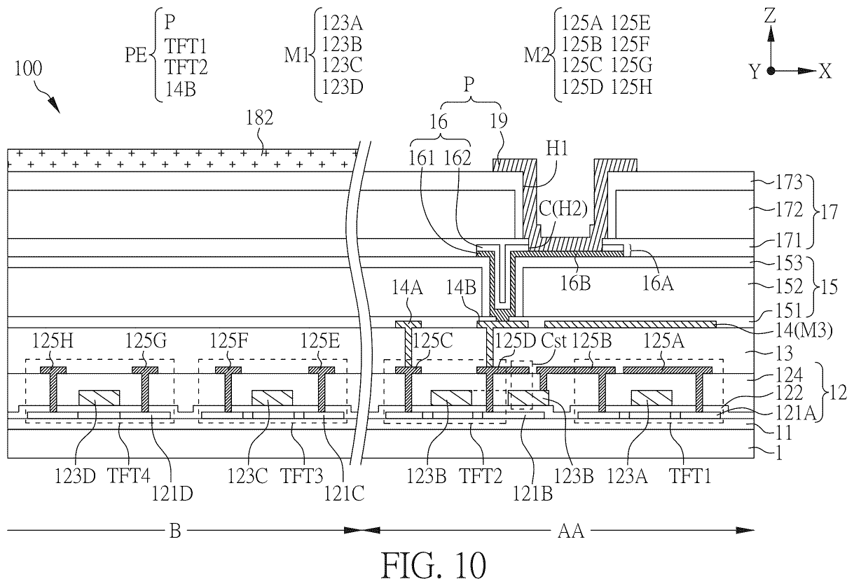

FIG. 8A to FIG. 8D are schematic views showing a method for manufacturing a printing substrate according to one embodiment of the present disclosure. FIG. 9 is a cross-sectional schematic view of a printing substrate according to one embodiment of the present disclosure. FIG. 10 is a cross-sectional schematic view of a printing substrate according to another embodiment of the present disclosure.

In one embodiment of the present disclosure, as shown in FIG. 8A, the method for manufacturing the printing substrate 100 may comprise: providing a substrate 1; forming a buffer layer 11, a driving layer 12, an insulating layer 13, a third metal layer M3 and another insulating layer 15 on the substrate 1 in sequence. Herein, the third metal layer M3 may comprise a power layer 14. The power layer 14 shown in the cross-sectional view of FIG. 8A may comprise the power line PL shown in the top view of FIG. 2. More specifically, the power layer 14 may comprise a first part 14A and a second part 14B, and the first part 14A and the second part 14B may be electrically connected to the second transistor TFT2 respectively, wherein the power line PL shown in the top view of FIG. 2 may be the first part 14A of the power layer 14. The driving layer 12 may comprise: a first transistor TFT1 and a second transistor TFT2 respectively disposed in the active region AA; and a third transistor TFT3 and a fourth transistor TFT4 respectively disposed in the peripheral region B. The first transistor TFT1 may be electrically connected to the second transistor TFT2, and the second transistor TFT2 may be electrically connected to the power layer 14. Then, the insulating layer 15 is patterned to form the opening H4.

Next, as shown in FIG. 8B, a conductive layer 16′ is formed on the insulating layer 15 and in the opening H4. More specifically, the conductive layer 16′ may comprise a first conductive layer 161′ and a second conductive layer 162′, and the first conductive layer 161′ and the second conductive layer 162′ are respectively formed on the insulating layer 15 and in the opening H4, wherein the first conductive layer 161′ and the second conductive layer 162′ may be electrically connected to the second part 14B of the power layer 14 through the opening H4 of the insulating layer 15.

Next, as shown in FIG. 8C, an insulating layer 17 is formed on the first conductive layer 161′ and the second conductive layer 162′. Then, the insulating layer 17 is patterned to form the first opening H1, wherein the first opening H1 exposes the surface of a part of the second conductive layer 162′. In the present embodiment, an etching gas may be used to pattern the insulating layer 17 (for example, the first insulating layer 171), while the etching gas may react with the surface of a portion of the second conductive layer 162′ to produce undesirable by-products.

Next, as shown in FIG. 8D, the second conductive layer 162′ is etched to form a concave C (i.e. the second opening H2), thereby forming a conductive layer 16 (including the first conductive layer 161 and the second conductive layer 162), wherein the second opening H2 and the first opening H1 are connected to expose a part of the first conductive layer 161. More specifically, the conductive layer 16 comprises a first part 16A and a second part 16B, and the first part 16A and the second part 16B are connected, wherein the first part 16A of the conductive layer 16 comprises parts of the first conductive layer 161 and the second conductive layer 162 (i.e. the first conductive layer 161 and the second conductive layer 162 covered by the insulating layer 17), and the second part 16B of the conductive layer 16 comprises the first conductive layer 161 exposed from the first opening H1 (i.e. another part of the first conductive layer 161 exposed from the first opening H1 of the insulating layer 17). When etching the second conductive layer 162′, the undesirable by-product generated by the reaction between the etching gas and the second conductive layer 162′ can be removed at the same time, leaving the unreacted lower layer of the first conductive layer 161. That is, the second conductive layer 162′ may be used to protect the first conductive layer 161′. Thus, the defect caused by the by-product generated by the conductive layer 16′ can be improved, and the reliability or yield of the printing substrate 100 can be improved.

Next, the first protection layer 181 is formed on the insulating layer 17, wherein the first protection layer 181 has a third opening H3, and the third opening H3 is connected to the first opening H1, thereby forming, for example, the printing substrate 100 of FIG. 9. In other embodiments of the present disclosure, the first protection layer 181 may be formed on the insulating layer 17 first, wherein the first protection layer 181 has a third opening H3, and the third opening H3 is connected to the first opening H1. Then, the exposed second conductive layer 162′ is patterned to form the second conductive layer 162 with the second opening H2 connected to the first opening H1, thereby forming, for example, the printing substrate 100 shown in FIG. 9.

In another embodiment of the present disclosure, the printing substrate 100 shown in FIG. 8D may then go through the steps, for example, shown in FIG. 3C and FIG. 3D to form a conductive layer 19′ (as shown in FIG. 3C) on the first protection layer 181 and the insulating layer 17 and in the first opening H1 of the insulating layer 17 and the second opening H2 of the second conductive layer 162, wherein a part of the conductive layer 19′ (as shown in FIG. 3C) may be disposed on the second part 16B of the conductive layer 16 and in contact with the second part 16B of the conductive layer 16 (i.e. a part of the conductive layer 19′ may be in contact with a part of the first conductive layer 161); and removing the first protection layer 181 and the part of the conductive layer 19′ (as shown in FIG. 3C) to form an anode 19 (as shown in FIG. 3D). Next, the second protection layer 182 (as shown in FIG. 10) is formed on the insulating layer 17 and locates in the peripheral region B, thereby forming, for example, the printing substrate 100 shown in FIG. 10. In this aspect, as shown in FIG. 10, the anode 19 may contact the first conductive layer 161 through the second opening H2 of the second conductive layer 162, so there can be good adhesion between the anode 19 and the first conductive layer 161, thereby improving the reliability of the printing substrate 100. In the present disclosure, the material of the conductive layer 19′ (as shown in FIG. 3C) may be referred to that of the anode 19, and is not described again here.

In the present disclosure, the methods for forming the buffer layer 11, the driving layer 12, the insulating layer 13, the third metal layer M3, the insulating layer 15, the conductive layer 16′, the insulating layer 17, the first protection layer 181, the second protection layer 182 and the conductive layer 19′ (as shown in FIG. 3C) may comprise chemical vapor deposition, physical vapor deposition, sputtering, coating or a combination thereof; but the present disclosure is not limited thereto. The “coating” may be, for example, dip coating, spin coating, roller coating, blade coating, spray coating or a combination thereof; but the present disclosure is not limited thereto. In addition, the method for forming the driving layer 12 may further comprise a patterning step. In the present disclosure, any suitable method may be used for patterning, which may comprise, for example, lithography and etching, wherein the etching may include dry etching, wet etching, or a combination thereof; but the present disclosure is not limited thereto. In the present disclosure, any suitable method may be used to remove the first protection layer 181 and a part of the conductive layer 19′ (as shown in FIG. 3C) and, for example, the first protection layer 181 together with the conductive layer 19′ (as shown in FIG. 3C) may be peeled off by external force; but the present disclosure is not limited thereto.

In one embodiment of the present disclosure, the printing substrate prepared by the aforesaid steps may be, for example, as shown in FIG. 9 and FIG. 10. Herein, the printing substrate shown in FIG. 9 is similar to that shown in FIG. 4, and the printing substrate shown in FIG. 10 is similar to that shown in FIG. 9, except for the following differences.

In one embodiment of the present disclosure, as shown in FIG. 9, the conductive layer 16 comprises a first conductive layer 161 and a second conductive layer 162, and the second conductive layer 162 is disposed on the first conductive layer 161, wherein the second conductive layer 162 has a second opening H2, the second opening H2 is the concave C of the conductive layer 16, and the second opening H2 exposes a part of the first conductive layer 161. More specifically, the conductive layer 16 comprises a first part 16A and a second part 16B and the first part 16A is connected to the second part 16B, wherein the first part 16A of the conductive layer 16 comprises a part of the first conductive layer 161 and the second conductive layer 162 (i.e. the first conductive layer 161 and the second conductive layer 162 covered by the insulating layer 17), and the second part 16B of the conductive layer 16 comprises the first conductive layer 161 exposed from the first opening H1. Thus, in the present disclosure, the first thickness T1 of the conductive layer 16 may be, for example, the sum of the thicknesses of the first conductive layer 161 and the second conductive layer 162, the second thickness T2 at the concave C of the conductive layer 16 may be, for example, the thickness of the first conductive layer 161. In one embodiment of the present disclosure, a difference between the first thickness T1 and the second thickness T2 may be greater than or equal to 10 nm (T1−T2≥10 nm); but the present disclosure is not limited thereto. In one embodiment of the present disclosure, the difference between the first thickness T1 and the second thickness T2 may be greater than or equal to 5 nm (T1−T2≥5 nm) and, for example, the difference between the first thickness T1 and the second thickness T2 may be between 5 nm and 1000 nm, for example, between 10 nm and 1000 nm, between 10 nm and 500 nm, between 10 nm and 200 nm, between 10 nm and 100 nm or between 10 nm and 50 nm; but the present disclosure is not limited thereto. In the present embodiment, the printing unit P may comprise the first conductive layer 161 and the second conductive layer 162; but the present disclosure is not limited thereto. In the present embodiment, the printing unit P, the first transistor TFT1, the second transistor TFT2 and the second part 14B of the power layer 14 may together form the printing element PE.

In one embodiment of the present disclosure, the first opening H1 may be connected to the second opening H2 of the second conductive layer 162. In one embodiment of the present disclosure, in the normal direction Z of the substrate 1, the second opening H2 of the second conductive layer 162 and the third opening H3 of the first protection layer 181 may be overlapped. In one embodiment of the present disclosure, the projection of the third opening H3 on the substrate 1 may be greater than the projection of the second opening H2 on the substrate 1.

In one embodiment of the present disclosure, the material of the first conductive layer 161 may be different from the material of the second conductive layer 162. The second conductive layer 162 may be used to protect the first conductive layer 161 to reduce the damage to the first conductive layer 161 during the manufacturing process, thereby improving the reliability of the printing substrate 100. In the present disclosure, the materials of the first conductive layer 161 and the second conductive layer 162 may respectively comprise titanium, molybdenum, gold, iridium, rhodium, palladium, an alloy thereof, a metal oxide or a combination thereof; but the present disclosure is not limited thereto. According to some embodiments, the first conductive layer 161 may comprise titanium, the second conductive layer 162 may comprise molybdenum; but the present disclosure is not limited thereto. According to some embodiments, the first conductive layer 161 and the second conductive layer 162 may respectively comprise a metal oxide, such as indium tin oxide (ITO). According to some embodiments, the first conductive layer 161 and the second conductive layer 162 may comprise different materials.

In one embodiment of the present disclosure, the printing substrate shown in FIG. 10 is similar to that shown in FIG. 9, except for the following differences. As shown in FIG. 10, the printing substrate 100 may not comprise the first protection layer 181 shown in FIG. 9, and the printing substrate 100 may comprise a second protection layer 182 disposed on the insulating layer 17 and in the peripheral region B. More specifically, in the normal direction Z of the substrate 1, the second protection layer 182 may be overlapped with the first driving unit D1 (as shown in FIG. 2), the second driving unit D2 (as shown in FIG. 2) and/or the electronic component E (as shown in FIG. 2) to prevent the direct contact between the aforesaid components and the electrolyte during the process for manufacturing the metal printed object, thereby reducing the risk of damage to the aforesaid components and improving the reliability of the printing substrate 100. In the present disclosure, the material of the second protection layer 182 may be as described above and is not described again here.

In one embodiment of the present disclosure, as shown in FIG. 10, the printing unit P further comprises an anode 19 disposed in one of the first openings H1 and the second opening H2 and contacting the exposed part of the first conductive layer 161. In other words, the anode 19 may be disposed on the second part 16B of the conductive layer 16, and a part of the anode 19 may be in contact with the second part 16B of the conductive layer 16. By applying electrical energy to the anode 19 of the printing substrate 100, the metal may be deposited/printed on the corresponding cathode plate near to the anode 19 to which the electrical energy is applied, thereby forming the metal printed object. In the present disclosure, the anode 19 may be an electrochemistry anode, and suitable material thereof may be as referred to above and is not described again here. In the present embodiment, the printing unit P may comprise the first conductive layer 161, the second conductive layer 162 and the anode 19; but the present disclosure is not limited thereto. In the present embodiment, the printing unit P, the first transistor TFT1, the second transistor TFT2 and the second part 14B of the power layer 14 may together form the printing element PE.

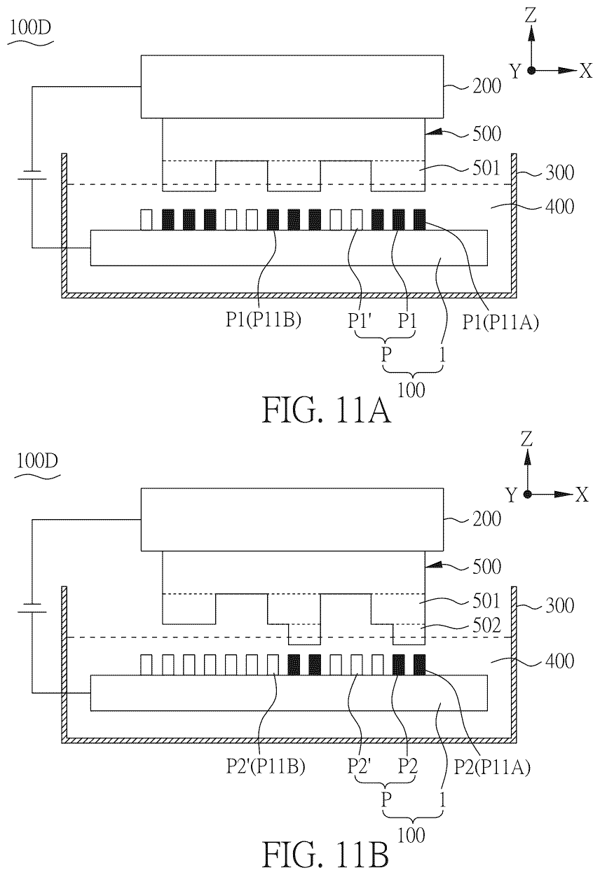

FIG. 11A and FIG. 11B are schematic views showing a method for manufacturing a metal printed object according to one embodiment of the present disclosure.

In one embodiment of the present disclosure, the method for manufacturing the metal printed object 500 may comprise: providing an electronic printing device 100D, wherein the electronic printing device 100D comprises a printing substrate 100, a cathode plate 200, a tank 300 and an electrolyte 400. As shown in FIG. 11A, the cathode plate 200 may be disposed opposite to the printing substrate 100. The printing substrate 100 and the electrolyte 400 may be disposed in the tank 300. In the present disclosure, the printing substrate 100 may be any printing substrate 100 illustrated in the aforesaid embodiments and is not described again here. For convenience of explanation, the printing substrate 100 comprising a plurality of printing units P on the substrate 1 is simply shown in FIG. 11A. In the present disclosure, the cathode plate 200 may comprise a cathode, and suitable material thereof may comprise copper, carbon, lead, zinc, aluminum, iron, an alloy thereof or a combination thereof; but the present disclosure is not limited thereto. In the present disclosure, the electrolyte 400 comprises ions of a metal, and the metal may be deposited or printed on the cathode plate 200 through electrochemical reaction to form the metal printed object 500. Herein, in the electrolyte 400, suitable metal may comprise gold, silver, zinc, nickel, copper, molybdenum, tin, tungsten, cobalt, or a combination thereof; but the present disclosure is not limited thereto. The electrolyte 400 may be, for example, copper sulfate, but the present disclosure is not limited thereto. When using the copper sulfate as the electrolyte, the metal printed object 500 is a printed object containing copper.

Next, a first printing is performed to print the metal in the electrolyte 400 on the cathode plate 200, thereby forming a first part 501 of the metal printed object 500, as shown in FIG. 11A. More specifically, when a first electrical energy is provided to a first group of printing units P1 among the plurality of printing units P of the printing substrate 100, the ions of the metal in the electrolyte 400 can receive electrons, and the metal in the electrolyte 400 can be deposited or printed on the cathode plate 200 corresponding to the first group of printing units P1 of the printing units P, thereby forming the first part 501 of the metal printed object 500. For example, in the third direction (for example, the normal direction Z of the substrate 1), the first part 501 of the metal printed object 500 may be formed at the position of the cathode plate 200 corresponding to the first group of the printing units P1. As shown in FIG. 11A, the printing units P1 that are supplied with electric energy are shown in black, and the printing units P1′ that are not supplied with electric energy are shown in white. In the present embodiment, as shown in FIG. 11A, other parts of the printing units P (i.e. the printing units P1′) are not supplied with electrical energy during the first printing, so no metal is deposited or printed on the cathode plate 200 corresponding to the other parts of the printing units P (i.e. the printing units P1′).

Next, a second printing is performed to print the metal in the electrolyte 400 on the cathode plate 200, and print the metal on the first part 501 of the metal printed object 500, thereby forming the second part 502 of the metal printed object 500, as shown in FIG. 11B. More specifically, when a second electrical energy is provided to the second group of printing units P2 among the plurality of printing units P of the printing substrate 100, the ions of the metal in the electrolyte 400 can receive electrons, and the metal in the electrolyte 400 can be deposited or printed on the cathode plate 200 corresponding to the second group of the printing units P2 of the printing units P and on the first part 501 of the metal printed object 500, thereby forming the second part 502 of the metal printed object 500. For example, in the third direction (for example, the normal direction Z of the substrate 1), the second part 502 of the metal printed object 500 may be formed at the position of the cathode plate 200 corresponding to the second group of the printing units P2. As shown in FIG. 11B, the printing unit P2 that are supplied with electric energy are shown in black, and the printing unit P2′ that are not supplied with electric energy are shown in white. In the present embodiment, as shown in FIG. 11B, other parts of the printing units P (i.e. the printing units P2′) are not supplied with electrical energy during the second printing, so no metal is deposited or printed on the cathode plate 200 corresponding to the other parts of the printing units P (i.e. the printing units P2′), and no metal is deposited or printed on the first part 501 of the metal printed object 500 corresponding to the other parts of the printing units P (i.e. the printing units P2′). In one embodiment of the present disclosure, when performing the second printing, a part of the first part 501 of the metal printed object 500 may be in contact with the electrolyte 400 (for example, immersing into the electrolyte 400) to facilitate the metal deposited or printed on the first part 501 of the metal printed object 500. In the present disclosure, the printing steps may be performed multiple times to form a three-dimensional (3D) metal printed object 500. According to some embodiments, when performing the printing steps multiple times, the same printing substrate 100 may be used. For example, the same printing units P may be used, and electrical energy may be supplied to different groups of the printing units during different prints. According to other embodiments, when performing the printing steps multiple times, different printing substrates may be used for different prints according to the needs.

In the present disclosure, “providing or applying electrical energy” comprises providing or applying voltage, current or a combination thereof; but the present disclosure is not limited thereto. In the present disclosure, “other part of the printing units” refers to the part of the printing units P that are not supplied with electrical energy; for example, when performing the first printing, other part of the printing units P is the printing units P1′ which may be the part of the printing units P other than the first group of the printing units P1; when performing the second printing, other part of the printing units P is the printing unit P2′ which may be the part of the printing units P other than the second group of the printing units P2. In one embodiment of the present disclosure, the first electrical energy may be different from the second electrical energy; but the present disclosure is not limited thereto. As shown in FIG. 11A and FIG. 11B, a part of the printing units P applied with the electrical energy in the first group of the printing units P1 among the printing units P may be the same as a part of the printing units P applied with the electrical energy in the second group of the printing units P2 among the printing units P, such as the printing unit P11A indicated in the figure. The printing unit P11A is applied with electrical energy during the first printing and also applied with electrical energy during the second printing. As shown in FIG. 11A and FIG. 11B, a part of the printing units P applied with electrical energy in the first group of the printing units P1 among the printing units P may be different from a part of the printing units P applied with electrical energy in the second group of the printing units P2 among the printing units P, such as the printing unit P11B indicated in the figure. The printing unit P11B is applied with electrical energy during the first printing and is not applied with electrical energy during the second printing. In one embodiment of the present disclosure, the first group of the printing unit P1 among the printing units P may be completely the same as, partially the same as or totally different from the second group of the printing units P2 among the printing units P; but the present disclosure is not limited thereto. The group of the printing units that is supplied with electrical energy for each printing may be adjusted according to the shape of the metal printed object to be formed.

In the present disclosure, according to some embodiments, the conductive layer 16 of the printing substrate has a first part 16A and a second part 16B, the first part 16A is covered by the insulating layer 17, and second part 16B is exposed from the first opening H1 of the insulating layer 17. The first thickness T1 of the first part 16A is greater than the second thickness T2 of the second part 16B. Through the designs of some embodiments of the present disclosure, the defects caused by the by-produces generated by the conductive layer 16 can be improved, thereby improving the reliability or yield of the printing substrate 100. According to some embodiments, by etching the conductive layer 16′, the conductive layer 16 having the concave C (for example, as shown in FIG. 4 and FIG. 5) or the second opening H2 (for example, as shown in FIG. 9 and FIG. 10) can be obtained. In other word, by designing the conductive layer 16 with thicknesses difference, the defects caused by the by-products generated by the conductive layer 16′ in the subsequent processes can be improved, thereby improving the reliability or yield of the printing substrate 100.

The above specific embodiments are to be construed as illustrative only and not in any way limiting of the remainder of the present disclosure.

Although the present disclosure has been explained in relation to its embodiment, it is to be understood that many other possible modifications and variations can be made without departing from the spirit and scope of the disclosure as hereinafter claimed.

1. An electronic printing device, comprising a printing substrate, wherein the printing substrate comprises:
a substrate having an active region and a peripheral region, wherein the active region is adjacent to the peripheral region;
a power layer disposed on the substrate;
an insulating layer disposed on the power layer; and
a plurality of printing units disposed on the substrate and disposed in the active region, wherein one of the plurality of printing units comprises:
a conductive layer disposed on the power layer and electrically connected to the power layer,
wherein the insulating layer has a first opening, a first part of the conductive layer is covered by the insulating layer, and a second part of the conductive layer is exposed by the first opening, wherein the first part of the conductive layer has a first thickness, the second part of the conductive layer has a second thickness, and the first thickness is greater than the second thickness.

2. The electronic printing device of claim 1, wherein the conductive layer comprises a first conductive layer and a second conductive layer, and the second conductive layer is disposed on the first conductive layer, wherein the first part of the conductive layer comprises a portion of the first conductive layer and a portion of the second conductive layer, and the first opening of the insulating layer exposes another portion of the first conductive layer.

3. The electronic printing device of claim 1, wherein a material of the conductive layer comprises titanium, molybdenum, gold, iridium, rhodium, palladium, an alloy thereof, a metal oxide or a combination thereof.

4. The electronic printing device of claim 2, wherein a material of the first conductive layer and the second conductive layer respectively comprises titanium, molybdenum, gold, iridium, rhodium, palladium, an alloy thereof, a metal oxide or a combination thereof.

5. The electronic printing device of claim 4, wherein the first conductive layer and the second conductive layer comprise different materials.

6. The electronic printing device of claim 1, wherein the printing substrate further comprises a first protection layer disposed on the insulating layer and locating in the active region and the peripheral region, wherein the first protection layer has a third opening, and the third opening of the first protection layer is connected to the first opening of the insulating layer.

7. The electronic printing device of claim 1, wherein the printing substrate comprises:
a driving layer disposed on the substrate, wherein the power layer is disposed on the driving layer and electrically connected to the driving layer; and
a second protection layer disposed on the insulating layer and locating in the peripheral region.

8. The electronic printing device of claim 1, wherein the insulating layer comprises a first insulating layer, a second insulating layer and a third insulating layer, and the second insulating layer is disposed between the first insulating layer and the third insulating layer, wherein the first insulating layer and the third insulating layer respectively comprises an inorganic material, and the second insulating layer comprises an organic material.

9. The electronic printing device of claim 1, wherein the printing substrate comprises a first driving unit and a scan line, the first driving unit is electrically connected to the scan line, and the scan line is electrically connected to the printing unit.

10. The electronic printing device of claim 1, wherein the printing substrate comprises a second driving unit and a data line, the second driving unit is electrically connected to the data line, and the data line is electrically connected to the printing unit.

11. The electronic printing device of claim 1, wherein the printing unit further comprises an anode disposed on the second part of the conductive layer and electrically connected to the conductive layer.

12. The electronic printing device of claim 11, further comprising a cathode plate disposed opposite to the printing substrate.

13. The electronic printing device of claim 12, further comprising a tank and an electrolyte, wherein the printing substrate and the electrolyte are placed in the tank, and the electrolyte comprises an ion of a metal.

14. A method for manufacturing a metal printed object, comprising:
providing an electronic printing device of claim 13;
providing a first electrical energy to a first group of printing units among the plurality of printing units of the printing substrate to perform a first printing, thereby printing the metal in the electrolyte on the cathode plate to form a first part of the metal printed object; and
providing a second electrical energy to a second group of printing units among the plurality of printing units of the printing substrate to perform a second printing, thereby printing the metal in the electrolyte on the cathode plate to form a second part on the metal printed object, wherein the second part is formed on the first part.

15. The method of claim 14, wherein the first electrical energy is voltage.

16. The method of claim 14, wherein the second electrical energy is voltage.

17. The method of claim 14, wherein the conductive layer comprises a first conductive layer and a second conductive layer, and the second conductive layer is disposed on the first conductive layer, wherein the first part of the conductive layer comprises a portion of the first conductive layer and a portion of the second conductive layer, and the first opening of the insulating layer exposes another portion of the first conductive layer.

18. The method of claim 14, wherein a material of the conductive layer comprises titanium, molybdenum, gold, iridium, rhodium, palladium, an alloy thereof, a metal oxide or a combination thereof.

19. The method of claim 17, wherein a material of the first conductive layer and the second conductive layer respectively comprises titanium, molybdenum, gold, iridium, rhodium, palladium, an alloy thereof, a metal oxide or a combination thereof.

20. The method of claim 19, wherein the first conductive layer and the second conductive layer comprise different materials.
